(19) United States
(12) Patent Application Publication
(10) Pub. No.: US 2008/0277709 A1
(43) Pub. Date: Nov. 13, 2008

(54) DRAM STRUCTURE

(76) Inventors: Tzung-Han Lee, Taipei City (TW); Chih-Hao Cheng, Taipei County (TW); Te-Yin Chen, Taoyuan County (TW); Chung-Yuan Lee, Tao-Yuan City (TW)

Correspondence Address: NORTH AMERICA INTELLECTUAL PROPERTY CORPORATION, P.O. BOX 506, MERRIFIELD, VA, 22116, US

(21) Appl. No.: 11/872,034

(22) Filed: Oct. 14, 2007

(30) Foreign Application Priority Data
May 10, 2007 (TW) 096116671

(51) Int. Cl. H01L 27/108

(52) U.S. Cl. 257/301; 257/E27.084

(57) ABSTRACT

A DRAM structure includes a substrate, a MOS transistor, a deep trench capacitor, a surface strap positioned on the surface of the substrate and interconnecting a drain of the MOS transistor and an electrode of the deep trench capacitor, wherein the sidewall and the top surface of the surface strap are covered with an insulating layer. A passing gate is positioned on the insulating layer.

### BACKGROUND OF THE INVENTION

1. Field of the Invention

The present invention relates to a DRAM structure, and more particularly to a DRAM structure preventing current leakage.

2. Description of the Prior Art

A DRAM, which is one of the most popular volatile memories utilized today, is composed of many memory cells. Each memory cell includes a MOS transistor and at least one capacitor connected in series. Through a word line and a bit line, the DRAM can be read and programmed.

FIG. 1 is a schematic diagram of a conventional trench capacitor DRAM structure. As shown in FIG. 1, the trench capacitor DRAM structure includes a MOS transistor 10 and a trench capacitor 20. The MOS transistor 10 is composed of a gate conductor 12, a gate dielectric layer 14, a source doping region 16 and a drain doping region 18. The trench capacitor 20 is composed of a conductive layer 11, a bottom electrode 23, a dielectric layer 24, a cap 26 and a Single-Sided Buried Strap (SSBS) 28. In addition, bias between the source doping region 16 and the drain doping region 18 is formed by a bit line 30 and a word line 32. Due to the bias, the current flows from the source doping region 16 to the drain doping region 18, then passes the SSBS 28, before finally being stored in the trench capacitor 20.

As electronic devices become smaller, the size of the DRAM memory cells is shrinking as well. However, because the distance between the elements is decreased, the contact area between the drain doping region 18 and SSBS 28 is also decreased, thereby increasing the contact resistance. Furthermore, the conventional trench capacitor DRAM structure forms a high electric field, which decreases the performance of the elements. In addition, the fabricating process of the SSBS, which is formed besides the collar of the capacitor 20 of the conventional trench capacitor DRAM structure, is complicated.

### SUMMARY OF THE INVENTION

To solve the above-mentioned problems, a DRAM structure is provided in the present invention. Unlike the conventional trench capacitor DRAM structure, the SSBS of the DRAM structure in the present invention is formed on the surface of the substrate, which simplifies the fabricating process.

The DRAM structure of the present invention includes: a substrate; a gate trench positioned in the substrate; a gate structure positioned in the gate trench; a gate dielectric layer positioned between the gate structure and the substrate; a source doping region and a drain doping region positioned in the substrate and adjacent to both sides of the gate structure respectively; a trench capacitor in the substrate and adjacent to the drain doping region; a gate channel in the substrate and between the source doping region and the drain doping region; a surface strap disposed on the substrate for electrically connecting the drain doping region and the trench capacitor; and a insulating layer covering the top surface of the surface strap.

The surface strap disclosed in the present invention provides a larger contact area between the drain doping region and the trench capacitor, thus the contact resistance is decreased. Meanwhile, the problem of high electric field in the conventional trench capacitor DRAM structure is solved. In addition, by forming the insulating layer on the surface strap, the passing gate can be positioned on the insulating layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a schematic diagram of a conventional trench capacitor DRAM structure.

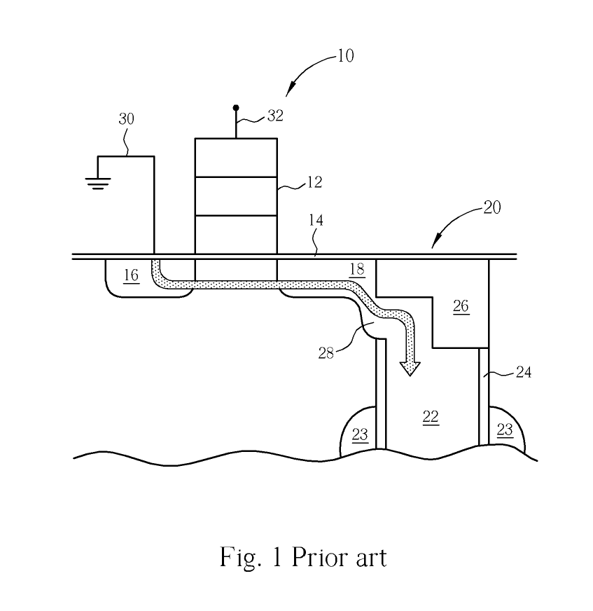

FIG. 2 shows a cross section of the DRAM structure of the present invention.

### DETAILED DESCRIPTION

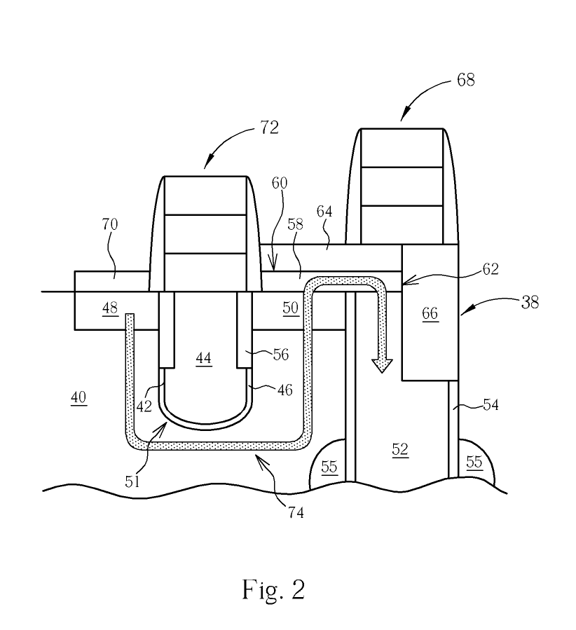

Please refer to FIG. 2, which shows a cross section of the DRAM structure of the present invention.

As shown in FIG. 2, the DRAM structure in the present invention comprises a substrate 40, wherein the substrate 40 comprises a semiconductor substrate, for example, silicon, germanium, carbon-silicon, silicon on insulator, silicon-germanium on insulator, compound semiconductor, or multi-layers semiconductor.

A gate trench 42 is positioned in the substrate 40. The bottom of the gate trench 42 is U-shaped in this example, but is not limited to this shape. A gate structure 44 comprising polysilicon is positioned in the gate trench 42. A gate dielectric layer 46 comprising silicon oxide, silicon nitride, silicon oxide, oxide-nitride, or oxide-nitride-oxide is positioned between the gate structure 44 and the substrate 40. A source doping region 48 is positioned at a side of the gate structure 44. A drain doping region 50 is positioned at the other side of the gate structure 44.

A gate channel 51 is between the source doping region 48 and the drain doping region 50. In addition, the gate channel is U-shaped which conforms to the bottom shape of the gate trench 42.

A trench capacitor 38 is adjacent to the drain doping region 50. The trench capacitor 38 comprises at least a conductive layer 52, a capacitor dielectric layer 54 covering the sidewall of the conductive layer 52 for isolating the conductive layer 52 and the substrate 40, and a bottom electrode 55, wherein the conductive layer 52 comprises polysilicon. Collar spacers 56 are positioned between the gate structure 44 and the drain doping region 50 and between the gate structure 44 and the source doping region 48. A surface strap 58 is positioned on the substrate 40 for connecting the drain doping region 50 and the conductive layer 52 electrically.

According to a preferred embodiment of the present invention, the surface strap 58 comprises metal, metal silicide, or nonmetal such as polysilicon and graphite. In addition, the preferred thickness of the surface strap 58 is between 500 Å and 800 Å, wherein the top surface 60 of the surface strap 58 is covered by an insulating layer 64.

An STI structure 66 is positioned in the conductive layer 52 for isolating the trench capacitor 38 and another memory cell, wherein the STI structure 66 connects to the insulating layer 64 and a sidewall 62 of the surface strap 58.

A passing gate 68 is positioned on the insolating layer 64 and a bit contact pad 70 covers the source doping region 48. A gate conductor 72 covers the gate structure 44.

Collar spacers 56 for decreasing the electric field formed by the source doping region 48 and the drain doping region 50 can be optional. If collar spacers 56 are formed, the junction depth of the drain doping region 50 and the source doping region 48 can be deeper in order to reduce the resistance.

A route 74 depicts the route of the current or the electron current formed by the bias. Unlike the conventional technology, the signal passes into the trench capacitor 38 through the surface strap 58 rather than the SSBS.

Due to the surface strap 58, the conductive layer 52 of the trench capacitor 38 is totally isolated from the substrate 40. Compared to the conventional technology where the SSBS needs to be positioned besides the trench capacitor, the fabricating process of the DRAM structure disclosed in the present invention is simpler.

In addition, the top surface 60 of the surface strap 58 is covered by the insulating layer 64. Therefore, a passing gate or a gate can be positioned on the insulating layer 64.

Those skilled in the art will readily observe that numerous modifications and alterations of the device and method may be made while retaining the teachings of the invention.

What is claimed is:

1. A DRAM structure, comprising:
a substrate;
a gate trench in the substrate;
a gate structure formed in the gate trench;
a source doping region and a drain doping region in the substrate and adjacent to both sides of the gate structure respectively;
a trench capacitor in the substrate and adjacent to the drain doping region;
a gate channel in the substrate and between the source doping region and the drain doping region; and
a surface strap disposed on the substrate for electrically connecting the drain doping region and the trench capacitor.

2. The DRAM structure of claim 1, further comprising an STI structure in the trench capacitor.

3. The DRAM structure of claim 1, wherein the thickness of the surface strap is between 500 Å and 800 Å.

4. The DRAM structure of claim 1, further comprising collar spacers positioned between the gate structure and the drain doping region and between the gate structure and the source doping region.

5. The DRAM structure of claim 1, further comprising a passing gate positioned above the trench capacitor.

6. The DRAM structure of claim 1, further comprising a gate conductor positioned on the gate structure.

7. The DRAM structure of claim 1, further comprising a bit contact pad connected electrically to the source doping region.

8. The DRAM structure of claim 1, wherein the gate channel is U-shaped.

9. The DRAM structure of claim 1, wherein the substrate is a semiconductor substrate.

10. The DRAM structure of claim 1, wherein the gate structure comprises polysilicon.

11. The DRAM structure of claim 1, wherein the trench capacitor comprises polysilicon.

12. The DRAM structure of claim 1, wherein the surface strap comprises metal.

13. The DRAM structure of claim 1, wherein the surface strap comprises metal silicide.

14. The DRAM structure of claim 1, wherein the surface strap comprises nonmetal.

15. The DRAM structure of claim 14, wherein the nonmetal comprises polysilicon and graphite.
